(19) United States
(12) Patent Application Publication
(10) Pub. No.: US 2023/0324017 A1
(43) Pub. Date: Oct. 12, 2023

(54) SELF-CHARGING SYSTEM FOR MULTIFUNCTION LIGHT BULBS

(71) Applicant: Green Business S.R.L., Pescara (IT)

(72) Inventors: Pietro Di Foglio, Pescara (IT); Andrea Di Foglio, Pescara (IT)

(21) Appl. No.: 18/028,121

(22) PCT Filed: Jul. 26, 2021
(86) PCT No.: PCT/IT2021/050231

§ 371 Date: Mar. 23, 2023

(30) Foreign Application Priority Data
Jul. 24, 2020 (IT) 102020000017983

(51) Int. Cl. F21S 9/03; H05B 47/19; F21K 9/237

(52) U.S. Cl. CPC F21S 9/03; F21K 9/237; H05B 47/19

(57) ABSTRACT

The invention refers to a lighting device, it concerns an electronic circuit, equipped with different technical devices, assembling in the same lighting device: and “e-storage” micro battery, an IOT wireless system, a mini thermoelectric generator and a photovoltaic film. This product makes it possible to replace the deteriorated and/or worn component characterized by each part is removable.

### CROSS-REFERENCE TO RELATED APPLICATIONS

The present Utility patent application is the National Phase filing under 35 U.S.C. 371 of the International Application No PCT/IT2021/050231 filed Jul. 26, 2021, entitled “SELF-CHARGING SYSTEM FOR MULTIFUNCTION LIGHT BULBS”, which PCT in turn claims priority to Italian Patent Application Number 102020000017983 filed on Jul. 24, 2020. The contents of these related applications are incorporated herein by reference for all purposes to the extent that such subject matter is not inconsistent herewith or limiting hereof.

### SCOPE OF APPLICATION

The present Invention relates generically to a lighting apparatus, such as a light bulb. More particularly, the invention relates to an electronic circuit for recovering available and otherwise dissipated energy, which can be consequently recycled during its normal operation phase. In this sense by equipping the new light bulb with various technical devices, the following will be assembled in the same lighting device: a m/n/battery, an IOT wireless system, a m/n/thermoelectric and photovoltaic generator.

### STATE OF THE ART

Lamps comprising multi-led or filament light sources and their associated power supply electronics are known, which now also include wireless DMX consoles and thus if necessary programmed. Also known are led bulbs which are widely replacing incandescent bulbs due to their better efficiency, the so-called “compact fluorescent” bulbs already allow significant energy savings, which can be increased by adopting this system just as the availability of small batteries allows integration of the emergency supply function inside the new led light bulbs.

These light bulbs have integrated leds operated by an electronic power supply that converts the 230V AC power supply into a form suitable for the leds. White led light bulbs have become so popular on the market that they have replaced almost every type of traditional filament source, from traditional tungsten filament light bulbs to the most modern halogen light bulbs. However, there is currently no lighting apparatus on the market (there are no patents on such inventive activity) capable of self-charging, storing, and using part of the energy during its normal operating cycle, thus integrating various technologies specifically structured with a specular integration for both photovoltaics and thermoelectricity, so as to enhance “light” and “heat” by recovering new energy, and above all without distorting the normal shapes and structures that characterise and distinguish current light bulbs.

### SHORT DESCRIPTION

In order to solve the above problem, lighting systems are currently in use which use various products which assemble wireless cards combined with energy saving devices. Nevertheless, the present invention, with respect to prior art, is proposed as a useful system for lighting indoor and/or outdoor environments in a more efficient way both in a “stand-alone” perspective and connected to the AC power mains.

The precise aim of the present invention is to assemble active and passive apparatuses in an “ALL-IN-ONE” logic, the different devices producing, storing, and monitoring electricity and then reusing it as light energy in order to light the surrounding environments. The possibility of quickly and easily replacing each element forming part of the present invention allows this action to occur for even only one of the components and connections of the various active and passive devices: generators, batteries, wireless system, & photovoltaic films.

A further inventive element is characterised by the fact that it has a dual functionality, i.e., it is functional in the same version both “indoors and outdoors”, where with the addition of a simple accessory, for outdoor use an integrated terminal is used with an additional plug-in battery which can be screwed in with a hole/ring loop and attached by a fixing device for hanging. In additional to the “indoor” and “outdoor” functions, it can function both as a “stand alone” type, i.e., isolated from the power mains, or in parallel with the power mains, to assist it and always provide a potential reduction in consumption. Other useful details to highlight are those concerning the use of an innovative “energy harvesting” solution for use in light bulbs, i.e., that of a seebeck/pelteir microcell tailor-made as necessary for this purpose.

Such lighting apparatus inside which is assembled:

A thermoelectric generator which recovers the temperature difference generated between the internal metal part of the lighting apparatus (due to the direct heat emitted by the led/light source) and the opposite part which, towards the outside, detects a lower temperature, close the ambient temperature, this temperature “delta” can potentially be increased by means of a specific aluminium tab structure included in a centre portion (2a), which can also have specific slits towards the outside, thus useful for the dissipation and cooling of one of the two sides of the thermoelectric generator/seebeck cell in question.

Integration of a battery as micro e-storage, where energy is self-produced by recovering both the diffused natural light and the artificial light emitted by the same light bulb during the operating phase.

In prior art, glass and/or Plexiglas, thanks tot heir known characteristics of transparency or semi-transparency, are able at the same time to ensure both the purpose of a protective casing and that of crossing by the light spectrum initially emitted by the light bulb, vice versa in the above mentioned invention, this component of spherical or parallelepiped shape can be characterised by the integration of materials with photovoltaic capabilities, available as required in various solutions, which may feature the integration of micro PV cells positioned crossways to the surface, or better in the thickness of the glass/Plexiglas, by means of the well-known LSC QD (quantum dot luminescent concentrator) technique, which characterises a transparent composite material by making it capable of concentrating and re-emitting more light by means of an internal optical nanostructure and conveying it towards a number of amorphous or polycrystalline silicon photovoltaic cells positioned at points which do not limit their ability to diffuse light.

Although, this solution is known to be able to also produce electricity using artificial light, it may be necessary to increase the thickness of this component to allow the integration of the photovoltaic cells. As an alternative, it is therefore possible to opt for cavity insertion on most of the working surface, or adhering to the working surface, of a specific photovoltaic cell film with a thickness of just a few microns, which, in this position, can also be applied with a double-sided structure, and therefore allow the capture of both any natural light towards its outer side, and artificial light towards the inside; this film is transparent/semi-transparent and preferably not positioned over the entire surface of the glass/Plexiglas of the light bulbs.

In the case of light bulbs of adequate volume, there is the predisposition to be able to also insert an IOT wireless card to remotely “domotize” each individual light bulb, in order to monitor the same light bulb together with the other connected ones, for the purpose of further increasing self-charging efficiency with production and accumulation of energy, including by means of a special APP to be able to detect and quantify for the user the energy savings obtained in real time.

Such a lighting apparatus comprises components which are functional both in a complementary and independent manner as well as able to replace deteriorated and/or end-of-life devices. Therefore, with respect to prior art, in this case we have a product that allows the reuse of a number of components and the recycling of other characterised by the fact that such components are easily removable by the end user.

In particular, the present invention innovatively describes a lighting device comprising at least one protective component for led/light bulb characterised by the fact that it comprises a plurality of transparent and semi-transparent mini photovoltaic cells, preferably positioned adherent to the surface of said protective component of led/light bulb, said protective component being designed to both emit and receive light from both an internal light source and an external light source, and further comprising at least one mini thermoelectric generator placed in the central portion of said lighting apparatus, or better located inside the cavity corresponding to the supporting body of said lighting device/centre portion 2a designed to also act as a heat sink, i.e., adjacent and below a metal plate on which said leds are positioned;

Comprising at least one rechargeable battery, used for storing energy produced by photovoltaic and thermoelectric sources, located in the lower portion 2b of said lighting device, which preferably corresponds to the part below the supporting body/centre portion 2a and to which is connected to lower metal terminal 2b for attachment and connection to the electrical power mains; and comprising a remote control and remote command device, micro relay/remote control switch, comprising a wireless card equipped with IOT (internet of things) technology to shut off at infeed the flow of energy from the mains when the battery has sufficient charge voltage, i.e., to shut off the mains energy like a switch and use the supply from the micro battery, vice versa when the energy of the micro battery is exhausted it automatically reconnects to the mains; positioned inside between the connection terminal and the central junction and support body;

and said protective component of the led/light bulb has been designed to be removable, by means of two pressure tabs/connectors.

Said lighting apparatus comprising in one embodiment a fixing device for external location inside which is a buffer battery and on the outside a ring.

Said lighting apparatus comprising at least a connection both in stand-alone mode and connected to the AC mains.

Said lighting apparatus comprising said two pressure tabs acting as a connectors for the photovoltaic cells and as a plug-in fixing element comprising a “plug & play” electrical contact, referred to as “+” positive and “−” negative respectively.

Said tabs act as removable devices, i.e., said tabs acting as positive and negative connectors allow removing and refitting the protective bulb from the lamp body (to which it is normally fixed by hot melt or by classical screwing on the body, while in this case the connectors act both as connectors and fixings), said bulb being removable, replaceable, and refittable, if necessary, from/to the central portion of said lighting apparatus.

Said lamp body being formed of said centre portion 2a and said lower metal terminal 2b for attachment and connection to the electrical power mains; said lighting apparatus included a micro contactor connected to receive impulses also from the wireless card and to close the incoming flow of energy from the mains when the battery has a useful charge voltage, i.e., to close, like a switch, the mains energy and to use the supply from the micro-battery, vice versa, when the energy of the micro-battery is exhausted it automatically reconnects to the mains according to the system program; said relay/remote control switch is positioned inside between the connection terminal and the central junction and support body of the apparatus.

Said lighting apparatus has numerous variants in which the protective component for the led/light bulb can have a spherical or other shape suitable for the purpose.

It should further be noted that the photovoltaic cell coating may be adherent to the surface of the bulb from either the outer or inner side of the same.

### BRIEF DESCRIPTION OF THE ILLUSTRATIONS

Further features and advantages of the invention will be more fully appreciable from the description of preferred, but not limiting, embodiments of the aforementioned lighting apparatus according to the present invention, wherein;

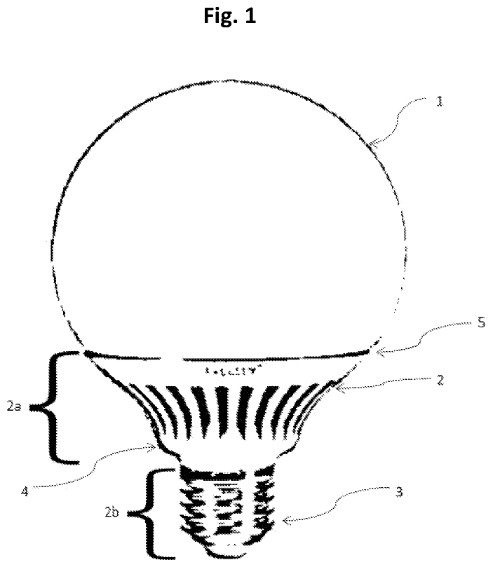

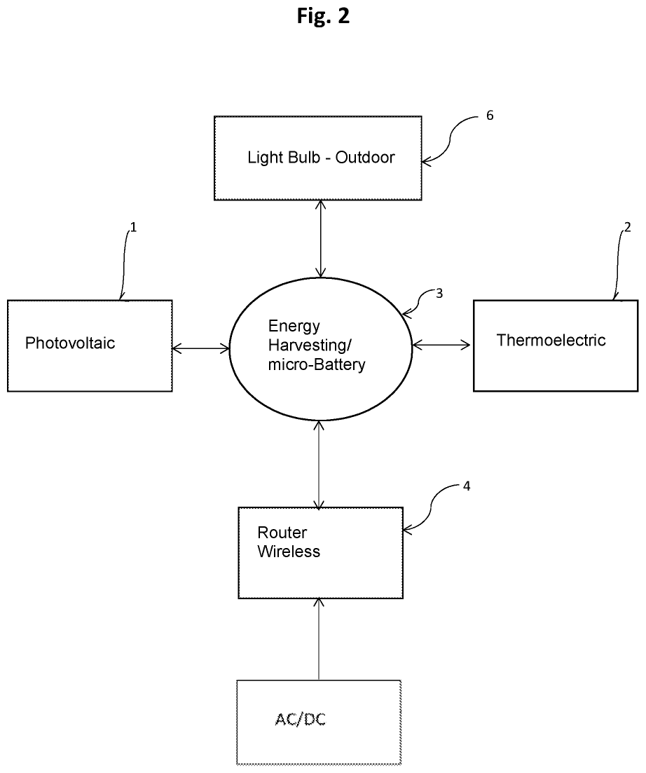

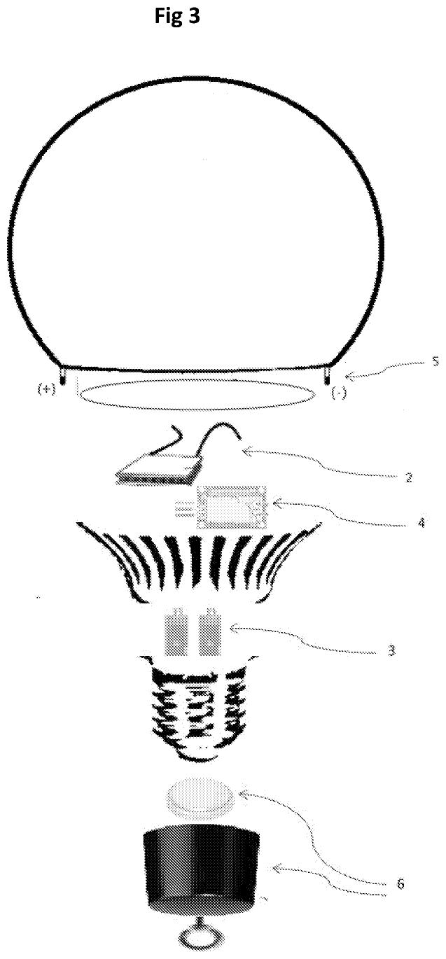

FIG. 1 represents a preferred embodiment with external view of the lighting apparatus inside which the various components are fitted; and a FIG. 2 comprising an explanatory block diagram of a preferred embodiment of the present invention; and a FIG. 3 illustrating an “exploded view” of the lighting apparatus according to a preferred embodiment of the present invention.

### DESCRIPTION OF THE ILLUSTRATIONS

With reference to FIG. 1, according to a preferred embodiment, at least the following are represented among the components:

A system provided with a double transparent/semi-transparent photovoltaic film 1, characterised by the fact that said film is adapted to capture natural light coming from outside and artificial light coming from inside;

A thermoelectric generator 2 characterised by the fact that the external metal part presents a different thermal difference with respect to the internal part so that this difference generates further energy which is stored in the micro batter(ies), the external aluminium support structure being useful for integrating accessories such as the same seebeck Peltier cell as well as simultaneously dissipating heat by means of a special img type tabbed structure;

At least one micro battery 3 that also stores the energy produced by the photovoltaic generator;

An IOT wireless card 4 characterised by the fact that it remotely monitors the self-charging process with energy production and storage;

A fixing device 5 in the underbody by means of two pressure tabs that can also act as a plug & play electrical contact as shown in FIG. 3.

By means of a block diagram, FIG. 2 illustrates the operation of the lighting apparatus characterised by;

A lighting apparatus 6 for also outdoor operation, comprises an ancillary fixing device, i.e., an end cap equipped with a counter thread which in turn can be screwed to the threaded terminal already present in the light bulb. This cap is further equipped with a buffer battery, which can be recharged separately and is useful for prolonged operation in supplying electrical energy in “outdoor” use, the eyelet located at the end serving as a through loop to hang in suspension the light bulb with a simple cable/loop, as can also be seen in FIG. 3.

A passive energy recovery system during normal operation of the lighting apparatus and consequent energy saving thanks to the partial and consequent self-charging exploited for domestic lighting, as well as for self-charging in am IOT perspective, the batteries are integrated in the threaded terminal as can be seen.

The operation of a micro pelt-seebeck 2 useful for exploiting and recovering energy from the difference between the internal and external temperature which is ambient temperature, by means of a tabbed heat sink integrated in the supporting body between the terminal and the light sphere.

A device for producing photovoltaic energy from artificial and/or natural light 1 by means of integration in the Plexiglas of the light sphere of transparent or semi-transparent photovoltaic solutions such as LSC or Spherical solar cells;

Operation of a wireless 4 card/router in the home automation field and remote control of the energy saving obtained and monitoring of the efficiency of the micro-battery located inside the light bulb as well as other storage systems that may be used as external accessories, compatible with Wi-Fi, radio, and Bluetooth modules.

Connection to either AC, mains, or DC, stand-alone system 7.

FIG. 3 shows an “exploded view” of the lighting apparatus showing components such as;

A cap 6 which can be screwed onto the threaded terminal of the light bulb, useful for “outdoor” use, with the possibility of further integration of a buffer battery to extend the lighting autonomy in the absence of a main supply.

A LED plate 8 that generates light and waste heat. As well as sequentially showing the degree of location of the different components.

It should be noted that in other embodiments, depending on the specific variations arising from the starting shapes of the light object/device, as well as the type of photovoltaic technologies used, the positioning of the active photovoltaic components may vary, including by means of the combined and multiple use of the same.

Preferably, this can be done by using flexible double-sided photovoltaic films with a choice of internal, external or cavity arrangement for LSC, spherical and conventional double-sided cells (compatible in perovskite, c-si, a-si, cis, cigs, cdte, opv, dssc) with respect to the spherical transparent or semi-transparent casing, (which may also have other shapes as mentioned above) while preserving its main characteristics of coating and protective casing of the led component and/or other types of light emission.\

In practice, the materials used as well as the dimensions and embodiments, cam be any according to the needs of the stat of the art. Finally, it is clear that numerous variations can be made to the device described herein, without departing from the principles of novelty inherent in the inventive idea, just as it is clear that, in the practical implementation of the invention, the material, shapes and sizes of the details illustrated can be according to requirements and the same can be replaced with others that are technically equivalent.

What is being claimed:

1. A lighting apparatus comprising at least one protective component (1) for leds/light bulbs characterised by the fact that it comprises a plurality of transparent and semi-transparent mini photovoltaic cells, preferably positioned adherent to the surface of said protective component of the leds/light bulbs, said protective component being designed to both emit and receive light from an internal light source as well as from an external light sources;
and, further comprising at least one mini thermoelectric generator (2) placed in the central portion of said lighting apparatus, or better located inside the cavity corresponding to the supporting body of said lighting apparatus, or adjacent to and below a plate (8) on which the leds are placed;
and further comprising at least one rechargeable battery (3), used to store energy produced by photovoltaic and thermoelectric sources, located in the lower portion (2b) of said lighting device, which preferably corresponds to the part below the supporting body/Centre portion (2a) and the metal terminal for attachment and connection to the electrical power mains;
and including a remote control and remote command devices, micro relay/telephone switch (4), including a wireless card equipped with IOT (Internet of things) technology to shut off the incoming flow of power from the mains, when the battery has sufficient charge voltage, i.e., to shut off the mains power like a switch and use the supply from the micro battery, vice versa when the power of the micro battery is exhausted it automatically reconnects to the power mains; positioned inside between the connection terminal and the central junction and support body;
and said protective component of the led/light bulb characterised by the fact that it has been designed to be removable, by means of two pressure tabs (5).

2. The lighting apparatus according to claim 1 comprising a fixing device for external location (6) inside which is a buffer battery and outside which a ring.

3. The lighting apparatus according to claim 1 comprising at least connection both in stand-alone mode and connected to the AC mains (7);

4. The lighting apparatus according to claim 1, comprising said two pressure tabs designed to also act as connectors for the photovoltaic cells as well as plug-in fixing element comprising an electrical contact preferably of the “plug & Play” type, indicated as “+” positive and “−” negative respectively;

5. The lighting apparatus according to claim 1, wherein said tabs act as removable devices i.e., said tabs acting as positive and negative connectors allow the protective bulb (1) to be removed and refitted from/to the lamp body, said protective bulb being therefore removable, replaceable, & refittable if necessary from/on the Centre portion (2a) of said lighting apparatus;

6. The lighting apparatus according to claim 1, comprising a micro contactor connected to receive impulses also from the wireless card and to shut off at infeed the power flow from the mains when the battery has a useful charge voltage i.e., to shut off the mains power like a switch and to use the supply from the micro battery, vice versa when the power of the micro battery is exhausted it automatically reconnects to the mains according to the system program; this relay/remote switch is located inside between the connection terminal and the central junction and support body of the apparatus;

7. The lighting apparatus according to claim 1, wherein the protective component for led/bulb can have a spherical or other suitable shape;

8. The lighting apparatus according to claim 1, wherein the photovoltaic cell coating may be adherent to the surface of the bulb from both the external land the internal side of the same.
